(19) United States
(12) Patent Application Publication
(10) Pub. No.: US 2009/0071528 A1
(43) Pub. Date: Mar. 19, 2009

(54) SOLAR CELL MODULE

(75) Inventor: Ga-Lane Chen, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/946,457

(22) Filed: Nov. 28, 2007

(30) Foreign Application Priority Data
Sep. 14, 2007 (CN) 200710201701.1

(51) Int. Cl. H01L 31/0232; H01L 31/04

(52) U.S. Cl. 136/246; 136/256

(57) ABSTRACT

The present invention relates to a solar cell module (1). The solar cell module includes a flexible solar cell (10) and a shape memory alloy layer (15) having a predetermined trained shape. The flexible solar cell has a first surface (100) configured for receiving solar radiation and a second surface (101) opposite to the first surface. The shape memory alloy layer is attached to the second surface of the flexible solar cell.

### CROSS REFERENCE TO RELATED APPLICATION

This application is related to commonly-assigned copending application Ser. No. ______, entitled “FLEXIBLE SOLAR CELL” (attorney docket number US 15052). Disclosures of the above-identified application are incorporated herein by reference.

### BACKGROUND

1. Technical Field

The present invention relates to a solar cell module.

2. Description of the Related Art

Photovoltaic devices, i.e., solar cells, are capable of converting solar radiation into usable electrical energy. The energy conversion occurs as the result of what is known as the photovoltaic effect. Solar radiation impinging on a solar cell and absorbed by an active region of semiconductor material generates electricity.

Solar cell offers a clean and effectively inexhaustible source of energy. Particularly, solar cell installed on a roof of a house had been recently proposed and gradually progressed to spread as an alternative source of energy used in a residential environment. However, a substrate of the solar cell is usually made of single-crystal silicon, poly-crystal silicon or glass, which is fragile, bulky and inflexible. Such solar cells can only receive solar energy in a predetermined direction.

What is needed, therefore, is a solar cell module, witch can receive solar radiation in different directions.

### SUMMARY

A solar cell module according to one present embodiment includes a flexible solar cell and a shape memory alloy layer having a predetermined trained shape. The flexible solar cell has a first surface configured for receiving solar radiation and a second surface at an opposite side of the flexible solar cell to the first surface. The shape memory alloy layer is attached on the second surface of the flexible solar cell.

Advantages and novel features will become more apparent from the following detailed description of the present flexible solar cell, when taken in conjunction with the accompanying drawings.

### BRIEF DESCRIPTION OF THE DRAWINGS

Many aspects of the present solar cell module can be better understood with reference to the following drawings. The components in the drawings are not necessarily drawn to scale, the emphasis instead being placed upon clearly illustrating the principles of the present solar cell module. Moreover, in the drawings, like reference numerals designate corresponding parts throughout the several views.

FIG. 1 is a cross-sectional view of a solar cell module in accordance with a first present embodiment;

FIG. 2 is a cross-sectional view of the solar cell illustrated in FIG. 1;

FIG. 3 is a cross-sectional view of a solar cell module in accordance with a second present embodiment;

FIG. 4 is a cross-sectional view of a solar cell module in accordance with a third present embodiment; and

FIG. 5 is a cross-sectional view of a solar cell module in accordance with a fourth present embodiment.

Corresponding reference characters indicate corresponding parts throughout the drawings. The exemplifications set out herein illustrate at least one preferred embodiment of the present solar cell module, in one form, and such exemplifications are not to be construed as limiting the scope of the invention in any manner.

### DETAILED DESCRIPTION OF THE EMBODIMENT

Reference will now be made to the drawings to describe preferred embodiments of the present solar cell module in detail.

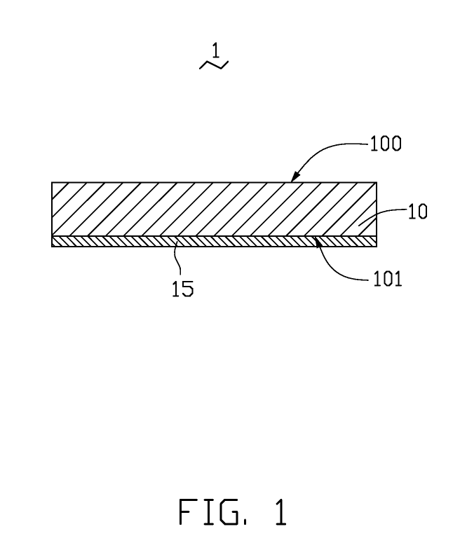

Referring to FIG. 1, a solar cell module 1 with a first present embodiment is shown. The solar cell module 1 includes a flexible solar cell 10. The flexible solar cell 10 includes a first surface 100 and a second surface 101 at an opposite side of the flexible solar cell 10 to the first surface 100. The first surface 100 is configured for receiving the solar radiation. A shape memory alloys (SMA, also known as a smart alloy or memory metal) layer 15 is attached on the second surface 101 of the flexible solar cell 10.

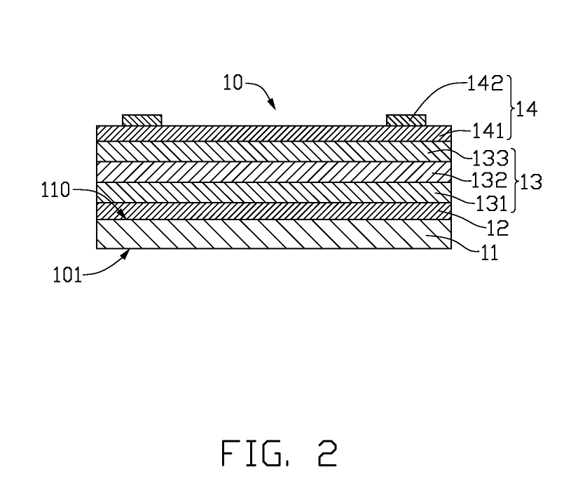

Referring to FIG. 2, the flexible solar cell 10 includes a substrate 11 having a first surface 110 and a second surface 111. A first surface 110 of the flexible solar cell 10 is opposite to the second surface 111. A first electrode layer 12 is formed on the first surface 110 of the flexible substrate 11. A semiconductor layer 13 is formed on the first electrode layer 12. A second electrode layer 14 is formed on the semiconductor layer 13. The second electrode layer 14 has a reverse polarity relative to the first electrode layer 12.

In the present embodiment, the substrate 11 is a flexible alloy of aluminum and magnesium (Al—Mg alloy) foil. The substrate 11 has a thickness in a range from about 10 μm to about 100 μm. The material of the substrate 11 also can be, but not limited to, Al, Mg, stainless steel, or polymer.

The first electrode layer 12 can be formed on the first surface 110 of the flexible substrate 11 by use of sputtering or depositing processes. A material of the first electrode layer 12 can be selected from the group consisting of silver (Ag), copper (Cu), Al, Al—Cu alloy, and alloy of copper and molybdenum (Cu—Mo alloy). A thickness of the first electrode layer 12 is in a range from about 0.1 μm to about 10 μm.

In the present embodiment, the semiconductor layer 13 includes a p-type semiconductor layer 131, an n-type semiconductor layer 133, and a p-n junction layer 132 located therebetween. The p-type semiconductor layer 131 is formed on and proximate to the first electrode layer 12.

The p-type semiconductor layer 131 is comprised of p-type amorphous silicon (p-a-Si). Preferably, the p-type semiconductor layer 131 is comprised of p-type amorphous silicon with hydrogen (p-a-Si:H). Other than p-a-Si, material used for the semiconductor layer 131 can also includes, but not limited to, subgroup III-V compounds and subgroup II-VI compounds, such as semiconductor material doped with nitrogen (N), phosphor (P), or arsenic (As) element. The semiconductor material doped with N, P, or As element can be gallium-nitrogen (GaN) and gallium indium phosphide (InGaP).

A material used for the p-n junction layer 132 is selected from subgroup III-V compounds and subgroup I-III-VI compounds, such as CdTe, CuInSe₂, CIGS(CuIn_{1-X}GaSe₂), etc. In the present embodiment, the p-n junction layer 132 can be formed on the p-type semiconductor layer 131 by use of chemical vapor deposition (CVD), or sputtering deposition processes. In alternative embodiments, any suitable process known to those skilled in the art and guided by the teachings herein provided may be used. The p-n junction layer 132 is configured for converting photos to hole-electron pairs to form a barrier field.

The n-type semiconductor layer is advantageously comprised, for example, of n-type amorphous silicon (n-a-Si), particularly, n-type amorphous silicon with hydrogen (n-a-Si:H). The material of the n-type semiconductor layer can also be selected from subgroup III-V compounds and subgroup II-VI compounds, such as semiconductor material doped with N, P, or As element. The semiconductor material doped with N, P, or As element can be GaN and InGaP.

It is can be understood that, the semiconductor layer 13 also can be a two-layer structure without the p-n junction layer 132.

The second electrode layer 14 is formed on the n-type semiconductor layer 133. The second electrode layer 14 includes at least one transparent conducting film 141 and metal contacts 142.

A material of the transparent conducting film 141 is selected from the group consisting of ITO (Indium Tim Oxides), zinc oxide (ZnO), tin dioxide (SnO2), SnO:In, Ga2O3:Sn, AgInO2:Sn, In2O3:Sn, In2O3:Zn, SnO2:Sb, and ZnO:Al. In the present embodiment, a transparent conduction film 141 is an ITO conducting film and is deposited onto the n-type semiconductor layer 133 in order to transport photo-generated charge carriers to external connections and minimize reflection. In the present embodiment, the transparent conducting film 141 can be applied to the n-type semiconductor layer 133 by use of sputtering deposition, a low pressure CVD (LPCVD), or a high pressure CVD (HPCVD) processes. In alternative embodiments, any suitable process known to those skilled in the art and guided by the teachings herein provided may be used.

In the present embodiment, metal contacts 142 can be formed on the transparent conductor layer 141 by using a silver screen printing process or a depositing process. Metal contacts 142 are utilized to collect and/or transmit the photo-generated current within solar cell 10 to an external load. Preferably, the metal contacts 142 ohmic contact with the transparent conductor layer 141.

The SMA layer 15 is in glued to the second surface 101 of the substrate 11 by adhesive. A material of the SMA layer 15 can be a one-way SMA or a two-way SMA. The material of the SMA layer 15 is selected from the group consisting of Ti—Ni alloy; copper (Cu) based SMA, such as Cu—Zn—Al alloy, Cu—Zn—Ca alloy, Cu—Al—Ni alloy, Cu—Al—Be alloy, Cu—Al-Mu alloy, Cu—Zn—Si alloy, and Cu—Al—Te alloy; and iron (Fe) based SMA, such as Fe—Pt alloy, Fe—Pd alloy, Fe—Cr—Ni alloy, Fe—Ni—C alloy, Fe—Mn alloy, Fe-33Ni-10Co-4Ti alloy, Fe-32Mn-6Si alloy, Fe-28Mn-6Si-5Cr alloy, Fe—Cr—Ni—Co—Mn—Si alloy, and Fe—Cr—Ni—Mn—Si alloy.

The SMA layer 15 has a predetermined trained shape such that it can regain its predetermined trained shape by itself during heating, or a higher ambient temperatures. These extraordinary properties are due to a temperature-dependent martensitic phase transformation from a low-symmetry to a highly symmetric crystallographic structure. Those crystal structures are known as martensite (at lower temperature) and austenite (at higher temperatures). In the present embodiment, the SMA layer 15 can be heated by supplying a current thereof. The flexible solar cell 10 is a typically flexible solar cell, so as to bend with the SMA layer 15.

In the present embodiment, the material of the SMA layer 15 can also be a single-crystal SMA. In this way, the flexible solar cell 10 is deformed due to the expansion of the SMA layer 15 during heating.

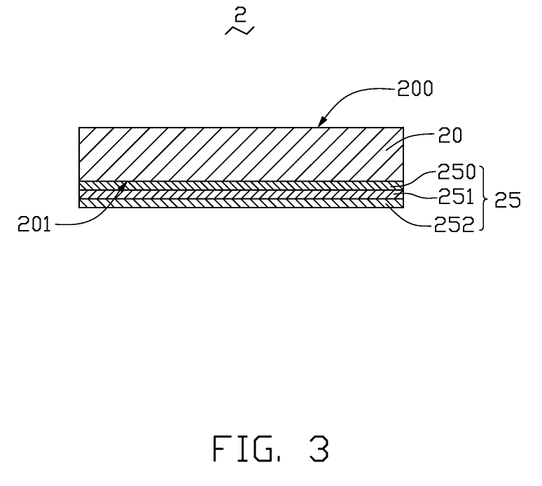

Referring to FIG. 3, a solar cell module 2 with a second present embodiment is shown. The solar cell module 2 includes a flexible solar cell 20. The flexible solar cell 20 includes a first surface 200 and a second surface 201 opposite to the first surface 200. The first surface 200 is configured for receiving the solar radiation. A SMA layer 25 is formed on the second surface 201. The structure of the solar cell module 2 is similar to that of the solar cell module 1 in the first embodiment, and the difference is that the SMA layer 25 is a pre-laminated, multi-layer structure having a plurality of SMA laminated thin film layers 250, 251, 252. Each SMA thin film layer 250, 251, 252 has a preformed/pretrained configuration different from each other and corresponds to different transformation temperature, such that the SMA layer transform into different forms when being heated to different temperatures. It is to be understood that, the structure of the SMA layer is not limited to the triple-layer structure illustrated in FIG. 3, and the SMA layer 15 can include more laminated layers. The more layers SMA layer 15 has, the more shape SMA layer 15 can form.

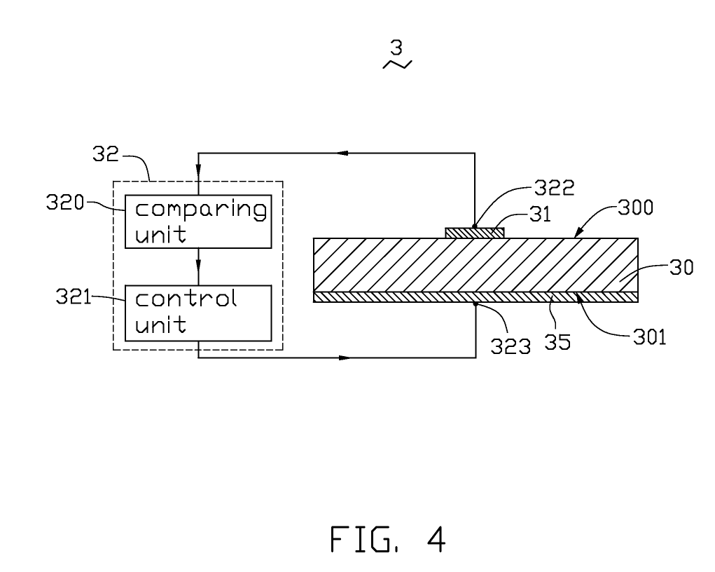

Referring to FIG. 4, a solar cell module 3 with a third present embodiment is shown. The solar cell module 3 includes a flexible solar cell 30. The flexible solar cell 30 includes a first surface 300 and a second surface 301 opposite to the first surface 300. The first surface 300 is configured for receiving the solar radiation. A SMA layer 35 is formed on the second surface 301. An optical detector 31 is attached to the first surface 300 for detecting an intensity of light incident on the flexible solar cell. The solar cell module 3 further includes a close-loop control circuit 32. The optical detector 31 can be a photo-thermal detector, a photoelectric detector, or a light pressure detector. In the present embodiment, the optical detector 31 is a photo-thermal detector, which can generate an output electric signal when irradiated with optical energy. The close-loop control circuit 32 has an in-put end 322 and an out-put end 323. The in-put end 322 is electrical connected with the optical detector 31. The out-put end 323 is electrical connected with the SMA layer 35.

In the present embodiment, the SMA layer 35 is a single structure layer. A material of the SMA layer 35 is preferred to be a two-way SMA. The two-way shape memory effect of the two-way SMA is that the material remembers two different shapes: one at low temperatures (martensite), and one at the high temperature shape (austenite).

In the present embodiment, the close-loop control circuit 32 includes a comparing unit 320 and a control unit 321. The comparing unit 321 is utilized to compare the intensity of solar radiation I with a predetermined intensity I₀. The value of the predetermined intensity I₀ is stored in the comparing unit 320. The SMA layer 35 has two predetermined trained shapes, martensite (at lower temperature) and austenite (at higher temperatures). When the comparing unit 320 determines that the intensity of solar radiation I detected by the optical detector 31 is less than the predetermined intensity I₀, the SMA layer 35 remains at martensite. When the comparing unit 320 determines that the intensity of solar radiation I is more than the predetermined intensity I₀, the comparing unit 320 generates a control signal to the control unit 321. The control unit 321 then supplies a current to the SMA layer 35 in accordance with the control signal. Once the heat generated by the current reaches or is higher than the point of martensite transformation temperature, the SMA layer 35 will activate to change from martensite to austenite. When the comparing unit 320 determines that the intensity of solar radiation I is less than the predetermined intensity I₀ again, the comparing unit 320 generates a control signal to the control unit 321. The control unit 321 then decreases intensity of the current in accordance with the control signal. Once the heat generated by the current is less than the point of martensite transformation temperature, the SMA layer 35 will activate to change from austenite to martensite. The choice of the predetermined intensity I₀ can be based on local sunshine cycle and sunshine intensity. For example, if the sunshine intensity at 10:00 AM is similar to the sunshine intensity at 16:00 PM, the intensity detected by the optical detector 31 at that moment can be selected as the predetermined intensity I₀. Because sunlight intensity from 10:00 AM to 16:00 PM is relative strong, the configuration of the SMA layer 35 is designed to be relatively flat so as to receive more solar radiation. However, when the sunlight intensity is weak in other period the SAM layer 35 is bent to appropriate bending shape so as to receive more solar radiation. In summary, in the present embodiment, the SMA layer 35 is trained to remember two different shapes: bending shape at low temperatures, and flat shape at the high temperatures. The bending shape of the SAM layer 35 can be selected from a spherical surface and a free-form surface in accordance with the local sunshine cycle and sunshine intensity.

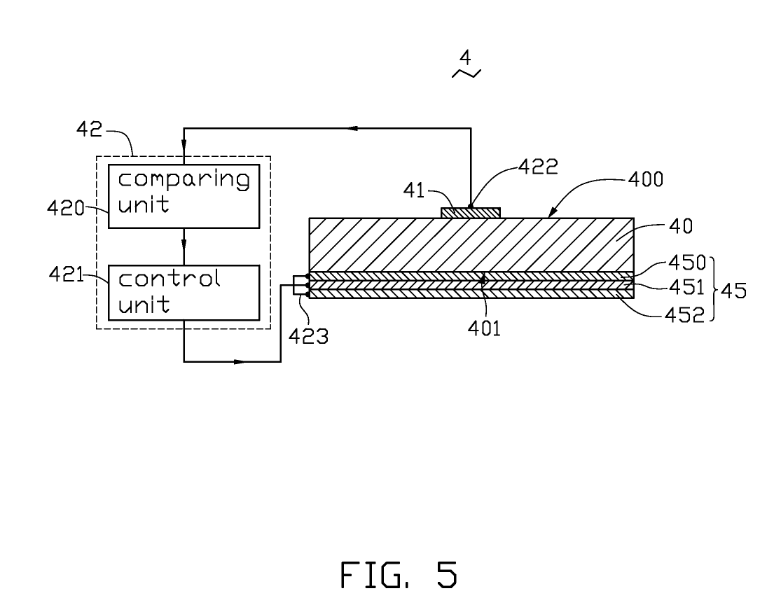

Referring to FIG. 5, a solar cell module 4 with a fourth present embodiment is shown. The solar cell module 4 includes a flexible solar cell 40. The flexible solar cell 40 includes a first surface 400 and a second surface 401 opposite to the first surface 400. The first surface 400 is configured for receiving the solar energy. A SMA layer 45 is formed on the second surface 401.

The structure of the solar cell module 4 is similar to that of the solar cell module 3 in the third embodiment, the difference is that the SMA layer 45 is a pre-laminated, multi-layer structure having a plurality of SMA laminated thin film layers 450, 451, 452. Each SMA thin film layer 450, 451, 452 has a preformed/pretrained configuration different from each other and corresponds to different transformation temperature, such that the SMA layer transform into different forms when being heated to different temperatures. An optical detector 41 is attached to the first surface 400. The solar cell module 4 further includes a close-loop control circuit 42. The close-loop control circuit 42 has an in-put end 422 and a plurality of out-put ends 423. The in-put end 422 is electrical connected with the optical detector 41. The plurality of out-put ends 423 is electrical connected with the SMA layer 45 separately.

In the present embodiment, the close-loop control circuit 42 includes a comparing unit 420 and a control unit 421. The comparing unit 421 is utilized to compare the intensity of solar radiation I with a plurality of predetermined intensities I₁, I₂, I₃. The value of the predetermined intensities I₁, I₂, I₃ are stored in the comparing unit 420. Each predetermined intensity corresponds to a certain period of time and a certain transformation temperature.

Compare with the conventional solar cell, the shape of the solar cell modules in the present embodiments can be changed in accordance with the intensity of the solar radiation, such that the solar cell module can receive solar radiation in different directions.

It is to be understood that the above-described solar cell module is not limited to be installed on the roof. Because of its lightweight and flexible properties, it can be widely used in aircraft, vessel, etc.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A solar cell module, comprising:
a flexible solar cell having a first surface configured for receiving solar radiation and a second surface at an opposite side of the flexible solar cell to the first surface,
a shape memory alloy layer having a predetermined trained shape, the shape memory alloy layer being attached on the second surface of the flexible solar cell.

2. The solar cell module as claimed in claim 1, wherein the flexible solar cell comprises a flexible substrate, a first electrode layer formed on the flexible substrate, a semiconductor layer formed on the first electrode layer, and a second electrode layer formed on the semiconductor layer.

3. The solar cell module as claimed in claim 2, wherein a material of the flexible substrate is selected from the group consisting of Al—Mg alloy, Al, Mg, stainless steel, and polymer.

4. The solar cell module as claimed in claim 1, wherein a material of the shape memory alloy layer is two-way shape memory alloy.

5. The solar cell module as claimed in claim 1, wherein the shape memory alloy layer has a single layer structure.

6. The solar cell module as claimed in claim 5, wherein a material of the shape memory alloy layer is single-crystal shape memory alloy.

7. The solar cell module as claimed in claim 1, wherein a material of the shape memory alloy layer is selected from the group consisting of Ti—Ni alloy, copper based shape memory alloy, and iron based shape memory alloy.

8. The solar cell module as claimed in claim 1, further comprising an optical detector for detecting an intensity of light incident on the flexible solar cell and a close-loop control circuit, the optical detector being attached to the first surface, the close-loop control circuit having an in-put end and an out-put end, the in-put end being electrically connected with the optical detector, the out-put end being electrically connected with the shape memory alloy layer.

9. The solar cell module as claimed in claim 8, wherein the optical detector is a photo-thermal detector, a photoelectric detector, or a light pressure detector.

10. The solar cell module as claimed in claim 8, wherein the close-loop control circuit comprises a comparing unit and a control unit, and a predetermined reference value of a light intensity stored in the comparing unit, the comparing unit is configured for comparing a value of the light intensity detected by the optical detector with the reference value and generating a control signal to the control unit, the control unit is configured for supplying a current to the shape memory alloy layer based on the control signal so as to change the shape of the shape memory alloy layer.

11. The solar cell module as claimed in claim 1, wherein the shape memory layer has a multi-layer structure having a plurality of shape memory alloy laminated thin film layers.

12. The solar cell module as claimed in claim 11, further comprising an optical detector for detecting an intensity of light incident on the flexible solar cell attached to the first surface and a close-loop control circuit, the close-loop control circuit having an in-put end and a plurality of out-put ends, the in-put end being electrically connected with the optical detector, each out-put end being electrically connected with the respective shape memory thin film layer.

13. The solar cell module as claimed in claim 12, wherein the optical detector is a photo-thermal detector, a photoelectric detector, or a light pressure detector.

14. The solar cell module as claimed in claim 11, wherein the close-loop control circuit comprises a comparing unit and a control unit, and at least one predetermined reference value of a light intensity stored in the comparing unit, the comparing unit is configured for comparing a value of the light intensity detected by the optical detector with the reference value and generating a control signal to the control unit, the control unit is configured for supplying a current to the shape memory alloy layer based on the control signal so as to change the shape of the shape memory alloy layer.
